(19) United States
(12) Patent Application Publication
(10) Pub. No.: US 2002/0076885 A1
(43) Pub. Date: Jun. 20, 2002

(54) Low resistance complementary metal oxide (CMOS) transistor and method

(76) Inventor: Ih-Chin Chen, Hsin-Chu City (TW)

Correspondence Address: TEXAS INSTRUMENTS INCORPORATED, P O BOX 655474, M/S 3999, DALLAS, TX, 75265

(21) Appl. No.: 09/737,310

(22) Filed: Dec. 14, 2000

Related U.S. Application Data
(60) Provisional application No. 60/175,040, filed on Jan. 7, 2000.

(51) Int. Cl. H01L 21/336; H01L 21/20; H01L 21/8238; H01L 21/338

(52) U.S. Cl. 438/270; 438/199; 438/183

(57) ABSTRACT

A method for forming a CMOS transistor with self-aligned cladding is provided that comprises forming a disposable gate structure (20) outwardly from a substrate (10) in a gate region (62) where the disposable gate structure (20) comprises a replaceable material (18). The method next provides for forming a source (40) and a drain (42) in the substrate (10) on opposite sides of the gate region (62). The method next provides for cladding the source region (40) and the drain region (42) using a self-aligned process. The method next provides for selectively removing the disposable gate structure (20), and forming a gate structure (70) in the gate region (62) vacated by the disposable gate structure (20). The method next provides for cladding a gate structure (70) using a self-aligned process.

### TECHNICAL FIELD OF THE INVENTION

This invention relates generally to the field of semiconductor devices, and more particularly to a low resistance complementary metal oxide (CMOS) transistor and method.

### BACKGROUND OF THE INVENTION

Modern electronic equipment such as televisions, telephones, radios and computers are generally constructed of solid state devices. Solid state devices are preferred in electronic equipment because they are extremely small and relatively inexpensive. Additionally, solid state devices are very reliable because they have no moving parts, but are based on the movement of charge carriers.

Solid state devices include transistors, capacitors, resistors and the like. One type of transistor is complementary metal oxide semiconductor (CMOS) transistors. CMOS transistors are a pair of transistors of opposite type used together. CMOS transistors may be used for low-dissipation logic circuits and the like.

The gates of CMOS transistors are typically constructed of a neutral material and later doped to opposite types such as n-type and p-type. The neutral gate material is generally a material that will not adversely affect the performance of either type of gate. As a result, the gate material may not be particularly well suited for each type of gate.

The gates of CMOS transistors may be constructed using disposable gate technology in which a disposable gate dielectric and/or gate body is formed and subsequently removed. A new gate dielectric and/or gate body may then be formed in a slot from which the disposable gate dielectric and/or gate body has been removed.

Increasingly, CMOS transistors are made smaller to reduce the size of electronic equipment. In addition, use of the devices in high performance logic requires faster operational speed and thus lower gate resistance for the CMOS transistors. Use of a thick silicide or metal cladding to lower gate resistance, however, is not compatible with conventional CMOS processing.

### SUMMARY OF THE INVENTION

In accordance with the present invention, a low resistance CMOS transistor and method are provided that substantially reduce or eliminate disadvantages and problems associated with conventional methods of forming CMOS transistors. More particularly, source, drain and/or gate contacts of the CMOS transistor are cladded by a self-aligned process to reduce the resistance and increasing the processing speed of the CMOS transistor.

According to an embodiment of the present invention, there is provided a method for forming a CMOS transistor with self-aligned cladding that includes forming a disposable gate structure outwardly from a substrate in a gate region where the disposable gate structure comprises a replaceable material. The method next provides for forming a source and a drain in the substrate on opposite sides of the gate region. The method next provides for cladding the source region and the drain region using a self-aligned process. The method next provides for selectively removing the disposable gate structure and forming a gate structure in the gate region vacated by the disposable gate structure. The method next provides for cladding the gate structure using a self-aligned process.

The present invention provides various technical advantages over conventional CMOS transistors and method for forming same. For example, one technical advantage is lowering the resistance of the source and drain contacts and the gate contact of the transistor thereby increasing the processing speed of the transistor. Another technical advantage of the present invention is cladding the CMOS contacts by use of a self-aligned process. As a result, cost of the high performance transistors is minimized. Other technical advantages may be readily apparent to one skilled in the art from the following figures, description and claims.

### BRIEF DESCRIPTION OF THE DRAWINGS

For a more complete understanding of the present invention and the advantages thereof, reference is now made to the following description taken in conjunction with the accompanying drawings, wherein like reference numbers represent like parts, and in which:

FIGS. 1A-1I are a series of cross-sectional diagrams illustrating a self-aligned method for cladding CMOS transistor contacts in accordance with one embodiment of the present invention; and

FIGS. 2A-2C are a series of cross-sectional diagrams illustrating a self-aligned method for cladding long gate CMOS transistor contacts in accordance with one embodiment of the present invention.

### DETAILED DESCRIPTION OF THE INVENTION

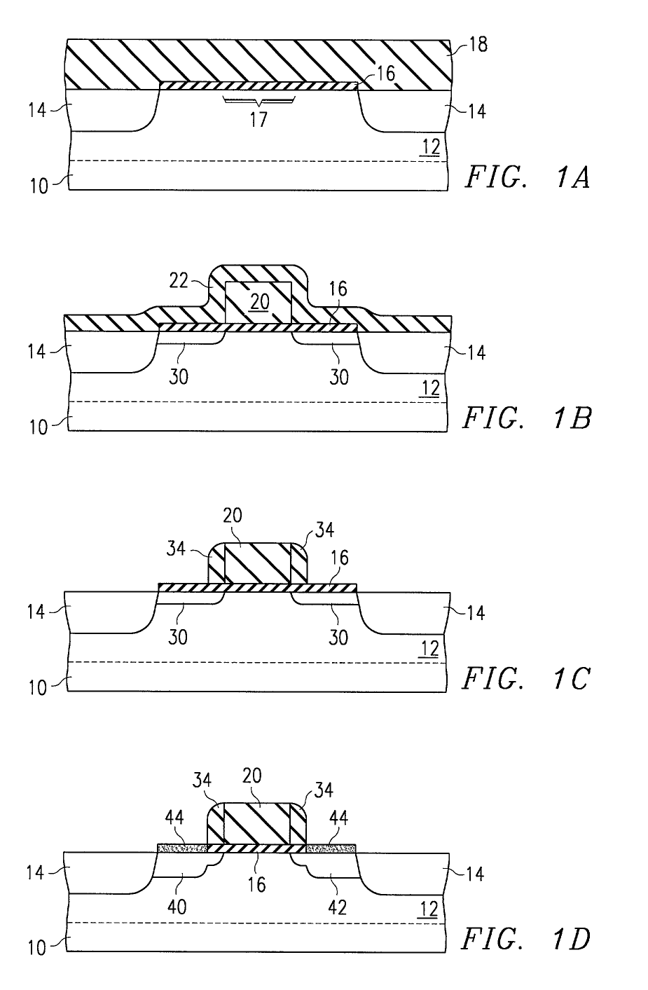

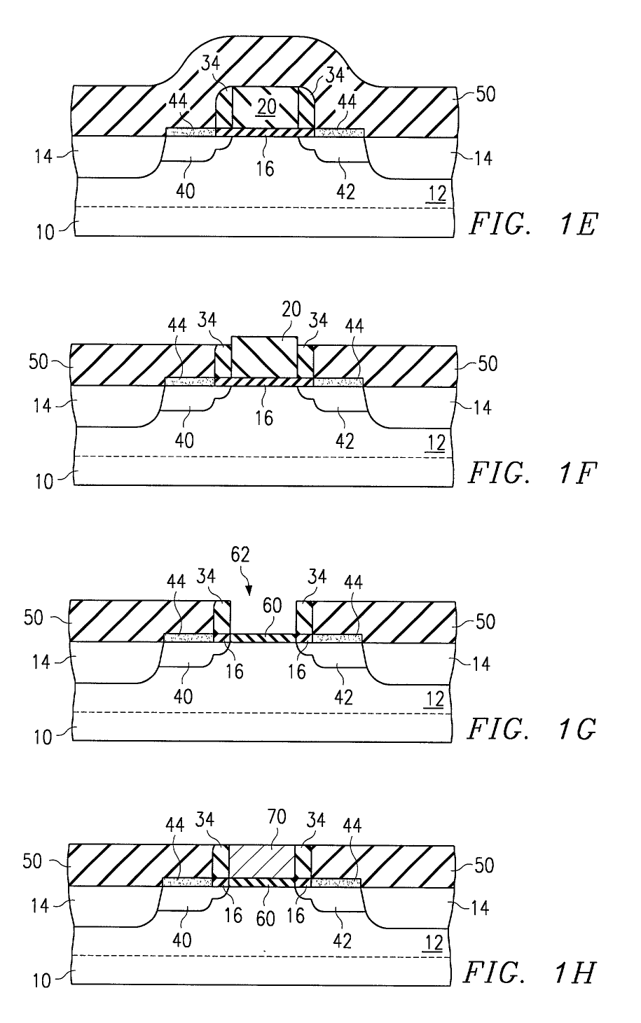

FIGS. 1A-1J illustrate fabrication of a high performance complementary metal oxide semiconductor (CMOS) transistor in accordance with one embodiment of the present invention. The CMOS transistor is cladded to minimize resistance and power use and to increase processing speed.

The CMOS transistor is used in logic and other high performance circuits.

Referring to FIG. 1A, an initial structure for fabricating the CMOS transistor includes a substrate 10. Substrate 10 may comprise any suitable semiconductor material or semiconductor material formed on a substrate. For example, substrate 10 may be a silicon wafer, a silicon wafer with previously fabricated embedded devices, an epitaxial layer grown on a wafer, a semiconductor on insulation (SOI) system, and the like.

Substrate 10 includes a CMOS well 12 with a shallow trench isolation (STI) structure 14 on either side thereby isolating an active area of substrate 10 above CMOS well 12. The active area includes a gate region 17 where a transistor gate will be formed. The CMOS transistor may be a short gate device or a long gate device. The long gate transistor has a wider gate region 17 as compared to the short gate transistor. In another embodiment, substrate 10 may be a p-type silicon substrate.

The CMOS transistor may be a p-type transistor with adjacent n-type transistors or be an n-type transistor with adjacent p-type transistors. For a p-type transistor, the CMOS well 12 comprises an n-well formed by doping the semiconductor layer with an n-type dopant such as phosphorous, arsenic or antimony. For the n-type transistor, CMOS well 12 comprises a p-well formed by doping the semiconductor layer with a p-type dopant such as boron.

A pad layer 16 is formed outwardly from substrate 10 over CMOS well 12. In the exemplary embodiment, pad layer 16 comprises a pad oxide layer on the order of 200 angstroms in thickness. Pad layer 16 facilitates the formation of integrated circuit devices on substrate 10 over CMOS well 12.

A replaceable gate material 18 is deposited outwardly from pad layer 16. As described in more detail below, replaceable gate material 18 is formed into a disposable gate structure during formation of a transistor on substrate 10. In the exemplary embodiment, replaceable gate material 18 comprises nitride deposited to a thickness on the order of 2000 angstroms. Replaceable gate material 18 may also comprise polysilicon or other material capable of being selectively removed from the pad oxide in the later formed gate insulator.

Referring to FIG. 1B, a disposable gate 20 is formed from replaceable gate material 18 on pad layer 16 between shallow trench isolation structures 14 in gate region 17. Replaceable gate material 18 is patterned with a gate pattern and etched to form disposable gate 20. Disposable gate 20 may be formed from replaceable gate material 18 using any suitable pattern and etch technique such as a photoresist and etch technique. As described in more detail below, disposable gate 20 will be removed and replaced with a permanent gate structure.

An sidewall insulator layer 22 may be deposited outwardly from disposable gate 20 and pad layer 16. Although the deposition of sidewall insulator layer 22 is optional prior to formation of the source and drain, it may be used to protect the substrate 10 from damage caused during formation of the source and drain. In the exemplary embodiment, sidewall insulator layer 22 comprises oxide deposited to a thickness on the order of 200 angstroms.

A medium doped drain (MDD) 30 is formed in substrate 10 adjacent on either side of disposable gate 20. In the exemplary embodiment, medium doped drains 30 are formed using an ion implant technique. During ion implantation for the transistor, active areas for complementary transistors and other structures on the substrate are masked to prevent contamination. Similarly, the active area for the transistor is masked during formation of the complementary sources and drains.

In one embodiment, the transistor is a p-type transistor and boron or phosphorus is implanted during the ion implant process at a dose of 1×10¹³ to 1×10¹⁵ at 10 KeV to 20 KeV. If the device is on an n-type substrate 10, arsenic may be implanted during the ion implant process at a dose of 1×10¹³ to 1×10₁₅ and between 20 KeV and 30 KeV.

Referring to FIG. 1C, sidewall insulators 34 are formed on opposite sides of disposable gate 20. If sidewall insulator layer 22 has not been previously deposited, an sidewall insulator layer 22 is deposited outwardly from disposable gate 20 and pad layer 16. Sidewall insulators 34 are formed from sidewall insulator layer 22 using an anisotropic etch. The anisotropic etch etches away sidewall insulator layer 22 vertically leaving sidewall insulators 34. As will be described in more detail below, sidewall insulators 34 prevent shorting between the gate and source and drain contacts. After formation of sidewall insulators 34, the structure may be densified using a standard densification technique.

Referring to FIG. 1D, a source 40 and a drain 42 are formed from medium doped drains 30. In the exemplary embodiment, an ion implant technique at a dose of 1×10¹⁵ to 5×10¹⁵ is used to create a deeper region than medium doped drains 30. During ion implantion, the sidewall insulators 34 act as spacers to prevent the formation of deep drains under the gate. The deeper portion of source 40 and drain 42 exists between shallow trench isolation structure 14 and spacer 34. As previously described, complementary transistors are masked during deep ion implantation for the transistors, and the transistor is masked during deep ion implantation for the complementary transistors. After deep ion implantation, pad layer 16 over source 40 and drain 42 is removed using a standard photoresist and etch technique. However, any suitable pattern and etch technique may be used.

A cladding material is deposited outwardly of the source 40 and drain 42, and the substrate 10 is then annealed to diffuse the source 40 and drain 42 and to define a channel under the disposable gate 20. Source 40 and drain 42 are annealed at a temperature of 800 degrees to 1000 degrees Celsius for a time period between 10 seconds and 20 minutes.

During the anneal, a low resistance cladding 44 is formed over source 40 and drain 42. In the exemplary embodiment, a silicide is used as low resistance cladding 44 and is on the order of 200 angstroms in thickness. The silicide may be formed by sputtering a reactive metal such as titanium or cobalt onto substrate 10. The reactive metal then reacts with the exposed silicon of the source 40 and drain 42 to form a silicide material. The silicide material forms a conductive alloy with low resistance to provide a low resistance path, or contact to source 40 and drain 42. After the silicide formation process, substrate 10 is placed in an acid bath where the nonreacted reactive metal is etched away leaving low resistance cladding 44. Accordingly, low resistance cladding 44 is formed using a self-aligned process that eliminates extra masking and patterning steps thereby reducing fabrication costs.

In another embodiment, a selective metal deposition process is used to form the cladding layer. The selective metal deposition process may be a selective tungsten deposition process or any other suitable selective metal deposition process. During the selective metal deposition process, the metal deposited on substrate 10 only adheres to the exposed silicon of the source 40 and drain 42. The selectively deposited metal is bonded with the source 40 and drain 42 to provide low resistance contacts for source 40 and drain 42. Accordingly, low resistance cladding 44 is self-aligned and no etch is needed after the anneal.

Referring to FIG. 1E, an insulation layer 50 is formed outwardly from the structure of FIG. 1D. Insulation layer 50 insulates source 40 and drain 42 from the rest of the CMOS transistor and provides a structure for later formation of contacts to the source 40 and drain 42. Insulation layer 50 conforms to the topography formed on substrate 10. In the exemplary embodiment, insulation layer 50 is an oxide deposited to a depth of 4000 to 6000 angstroms. The resulting structure may then be densified at 7000 to 8000 Celsius in a furnace containing nitrogen or argon gas. However, densification is not a required step in forming the CMOS transistors of the present invention.

Referring to FIG. 1F, the structure of FIG. 1E is planarized to expose the disposable gate 20. In the exemplary embodiment, the structure of FIG. 1E is planarized using a chemical mechanical polishing (CMP) process to remove the excess insulation layer 50 above disposable gate 20. In another embodiment, the structure of FIG. 1E is planarized using a suitable etching technique.

Referring to FIGS. 1G-1I, the disposable gate 20 for the transistor is replaced with a permanent gate. During this process, the complementary transistors and other areas of substrate 10 are masked. After the disposable gate 20 of a certain type (n or p) of transistor has been replaced, that transistor type is masked and the disposable gates of the complementary transistors are replaced.

Referring to FIG. 1G, disposable gate 20 is removed to make room for a permanent gate structure. In the exemplary embodiment, disposable gate 20 is removed by exposing the nitride of disposable gate 20 to phosphoric acid. The phosphoric acid etches away the nitride and leaves the surrounding oxide sidewall insulators 34.

Pad layer 16 is removed in the area vacated by disposable gate 20 using an appropriate pattern and etch technique. In the exemplary embodiment, pad layer 16 is etched using a fluorine etch. The fluorine etch should be carefully timed to remove the pad layer 16 while minimizing the removal of other exposed oxides such as insulation layer 50 and sidewall insulators 34. The removal of disposable gate 20 and pad layer 16 creates a gate structure area 62. At the base of gate structure area 62 is the outer surface of substrate 10 that includes portions of diffused source 40 and diffused drain 42.

A gate insulator 60 is formed in the base of gate structure area 62. In the exemplary embodiment, gate insulator 60 is an oxide grown to a depth of 200 angstroms.

Referring to FIG. 1H, a gate structure 70 is formed in gate structure area 62 using a suitable transistor gate material. For p-type transistors, the gate material may be polysilicon in-situ doped with p-type dopants. For n-type transistors, the gate material may be polysilicon in-situ doped with n-type dopants. Titanium nitride or other suitable metals may also be used for one or more of the gate structures. Gate structure 70 functions as a gate conductor. In the exemplary embodiment, a layer of polysilicon is deposited filling gate structure area 62. In addition, the deposited polysilicon conformally covers the outer surface of substrate 10. The polysilicon, or other material, layer deposited on the outer surface of substrate 10 to form gate structure 70 is submitted to a chemical mechanical polishing (CMP) process to remove the excess polysilicon, or other material, thereby leaving gate structure 70 in gate structure area 62.

After forming gate structure 70, cladding material is formed outward of the gate structure 70. As previously described, the cladding material may be silicide or metal reacted with exposed gate material to form a low-resistance gate cladding 80 outwardly from gate structure 70. Low resistance gate cladding 80 provides a low resistance signal path, or contact, to gate structure 70. Contacts to the CMOS transistor source, drain and gate may then be conveniently formed.

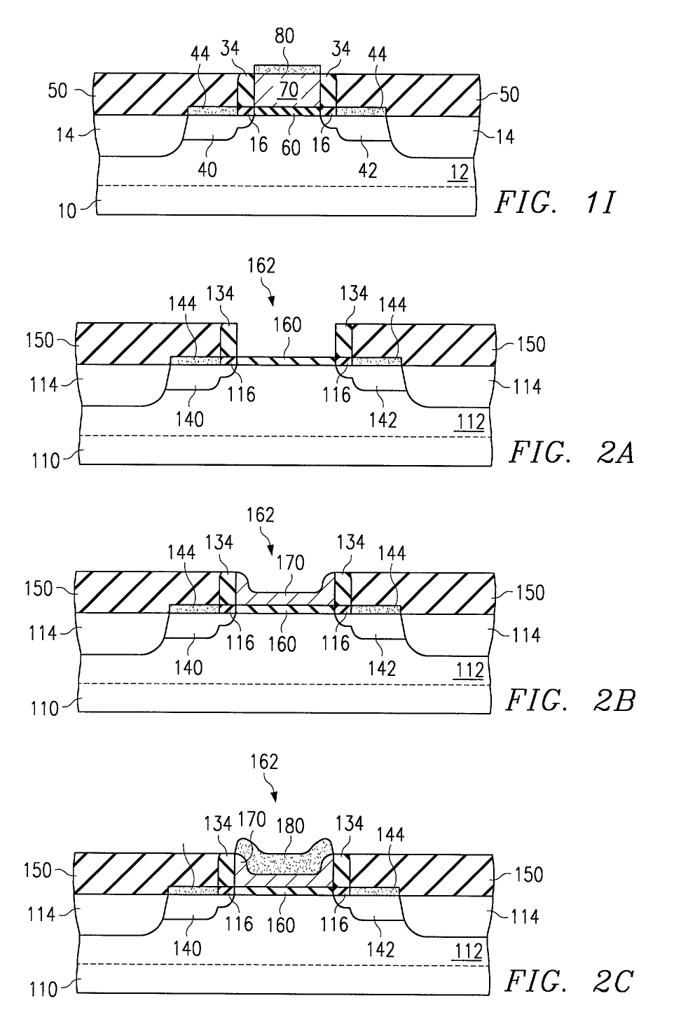

FIGS. 2A-2C illustrate cladding of a long gate CMOS transistor in accordance with one embodiment of the present invention. A long gate transistor has a wider gate as compared to a short gate transistor which was illustrated in FIGS. 1A-1J. Referring to FIG. 2A, an initial structure includes a substrate 110, a CMOS well 112, shallow trench isolation structures 114, a pad layer 116, sidewall insulators 134, a source 140, a drain 142, a low resistance cladding 144, an insulation layer 150, a gate insulator 160, and a gate structure area 162 formed as previously described in connection with FIGS. 1A-1G.

Referring to FIG. 2B, a gate structure 170 is formed with a suitable transistor gate material such as polysilicon or titanium nitride as previously described with relation to gate structure 70 of FIG. 1H. Since gate structure area 162 is wider for a long gate transistor, gate structure 170 conforms to the long gate structure and does not completely fill gate structure area 162.

Referring to FIG. 2C, a low resistance gate cladding 180 is formed outwardly from gate structure 170 similarly to the low resistance gate cladding 80 of FIG. 1I by depositing and reacting a cladding material with the gate material. Since the long gate transistor has a recessed area for gate structure 170, low resistance gate cladding 180 conformally fills the recess of gate structure 170. Contacts to source 140, drain 142 and gate 170 may be conventionally formed.

Thus, it is apparent that there has been provided in accordance with the present invention, a method for cladding CMOS transistor regions that satisfies the advantages as set forth above such as lower resistance gate, source, and drain contacts resulting in faster processing speeds. Although the present invention and its advantages have been described in detail, it should be understood that various changes, substitutions, and alterations may be readily apparent to those skilled in the art and may be made without departing from the spirit and the scope of the present invention as defined by the following claims.

What is claimed is:

1. A method for forming a CMOS transistor with self-aligned cladding, comprising:
forming a disposable gate structure outwardly from a substrate in a gate region, the disposable gate structure comprising a replaceable gate material;
forming a source and a drain in the substrate on opposite sides of the gate region;
cladding the source and the drain using a self-aligned process;
selectively removing the disposable gate structure;
forming a gate structure in the gate region vacated by the disposable gate structure; and
cladding the gate structure using a self-aligned process.

2. The method of claim 1, wherein cladding the source, the drain and the gate structure further comprises forming a silicide layer on the source, the drain and the gate structure to form a low resistance contact.

3. The method of claim 2, wherein forming the silicide layer further comprises:
depositing a reactive metal onto the substrate;
reacting the reactive metal with the substrate to form the silicide layer; and
selectively removing non-reacted reactive metal from the substrate.

4. The method of claim 3, wherein the reactive metal comprises titanium and the substrate comprises a silicon wafer.

5. The method of claim 3, wherein the reactive metal comprises cobalt and the substrate comprises a silicon wafer.

6. The method of claim 1, wherein cladding the source, the drain and the gate structure further comprises selectively depositing a low resistance metal on the source, the drain and the gate structure.

7. The method of claim 6, wherein the low resistance metal comprises tungsten.

8. The method of claim 1, wherein the replaceable gate material comprises nitride.

9. The method of claim 1, wherein the replaceable gate material comprises polysilicon.

10. A method for forming a CMOS transistor with self-aligned cladding, comprising:
forming a disposable gate structure outwardly from a substrate in a gate region, the disposable gate structure comprising a replaceable gate material;
forming a source and a drain in the substrate on opposite sides of the gate region;
blanket depositing a reactive metal onto the substrate;
reacting the reactive metal with the substrate in the source and the drain areas to form a silicide layer over the source and the drain, the silicide layer providing a low resistance contact;
selectively removing non-reacted reactive metal from the substrate;
selectively removing the disposable gate structure;
forming a gate structure in the gate region vacated by the disposable gate structure.

11. The method of claim 10, further comprising:
blanket depositing a reactive metal onto the substrate;
reacting the reactive metal with the gate structure to form a silicide layer over the gate structure, the silicide layer providing a low resistance contact;
selectively removing non-reacted reactive metal from the substrate.

12. The method of claim 10, wherein the reactive metal comprises titanium and the substrate comprises a silicon wafer.

13. The method of claim 10, wherein the reactive metal comprises cobalt and the substrate comprises a silicon wafer.

14. The method of claim 10, wherein the replaceable gate material comprises nitride.

15. The method of claim 10, wherein the replaceable gate material comprises polysilicon.

16. A method for forming a CMOS transistor with self-aligned cladding, comprising:
forming a disposable gate structure outwardly from a substrate in a gate region, the disposable gate structure comprising a replaceable gate material;
forming a source and a drain in the substrate on opposite sides of the gate region;
selectively depositing a metal on the source and the drain, the metal adhering only to the source and the drain;
bonding the metal with the substrate in the source and the drain areas to form a low resistance interface between the metal and the source and the drain;
selectively removing the disposable gate structure;
forming a gate structure in the gate region vacated by the disposable gate structure.

17. The method of claim 16, further comprising:
selectively depositing a metal on the gate structure, the metal adhering only to the gate structure;
bonding the metal with the gate structure to form a low resistance interface between the metal and the gate structure.

18. The method of claim 16, wherein the low resistance metal comprises tungsten.

19. The method of claim 16, wherein the replaceable gate material comprises nitride.

20. The method of claim 16, wherein the replaceable gate material comprises polysilicon.
